(19) United States
(12) Patent Application Publication
(10) Pub. No.: US 2026/0173257 A1
(43) Pub. Date: Jun. 18, 2026

(54) ELECTRONIC COMPONENT-EMBEDDED SUBSTRATE

(71) Applicant: SAMSUNG ELECTRO-MECHANICS CO., LTD., Suwon-si (KR)

(72) Inventors: Gyoo Tae BAE, Suwon-si (KR); So Bean JANG, Suwon-si (KR)

(73) Assignee: SAMSUNG ELECTRO-MECHANICS CO., LTD., Suwon-si (KR)

(21) Appl. No.: 19/307,407

(22) Filed: Aug. 22, 2025

(30) Foreign Application Priority Data
Dec. 12, 2024 (KR) 10-2024-0184767

(51) Int. Cl. H05K 1/02; H05K 1/03; H05K 1/11; H05K 1/18

(52) U.S. Cl. CPC H05K 1/0271; H05K 1/0306; H05K 1/113; H05K 1/185; H05K 2201/09527; H05K 2201/096; H05K 2201/09609; H05K 2201/09618

(57) ABSTRACT

An electronic component-embedded substrate includes a glass layer having a through-portion that extends between an upper surface and a lower surface of the glass layer. A metal layer is at least partially embedded in the glass layer and partially exposed through a wall surface of the through-portion. An electronic component is at least partially disposed in the through-portion. An encapsulant fills at least a portion of the through-portion and buries at least a portion of the electronic component.

### CROSS-REFERENCE TO RELATED APPLICATION(S)

This application claims the benefit of priority to Korean Patent Application No. 10-2024-0184767 filed on Dec. 12, 2024 with the Korean Intellectual Property Office, the disclosure of which is incorporated herein by reference in its entirety.

### TECHNICAL FIELD

The present disclosure relates to an electronic component-embedded substrate.

To respond to strategies for high performance and miniaturization of semiconductors, the required levels of miniaturization and high density for printed circuit boards have been increasing. For example, in order to manufacture high-end products such as server substrates, a high number of layers and a large body have been required. However, as the number of wiring layers increases and a size of a body increases, a substrate may be more vulnerable to warpage. In order to solve such an issue, using a glass core has been considered. In order to embed an electronic component in a glass core, a cavity may be processed in the glass core, and electronic components may be disposed therein. However, when the cavity is processed in the glass core, breakage or cracks in glass may occur during a cutting process. In addition, breakage or cracks in the glass may also occur due to impacts or the like during a process of disposing an electronic component in the cavity formed in the glass core.

### SUMMARY

An aspect of the present disclosure is to provide an electronic component-embedded substrate including a glass layer in which a through-portion is formed for embedding an electronic component, the electronic component-embedded substrate capable of preventing breakage or cracks from occurring in glass during a process of processing the through-portion and/or a process of disposing the electronic component in the through-portion, thereby improving yield.

A metal layer may be pre-formed on a cutting line of a dummy region, in which a through-portion of a glass layer is to be formed, using slit processing and slit wall plating, and then an insulating layer may be stacked on the glass layer. Thereafter, the through-portion, exposing the metal layer, may be formed, and breakage and cracks in the glass layer may be prevented through the remaining metal layer.

According to an aspect of the present disclosure, there is provided an electronic component-embedded substrate including a glass layer, a through-portion passing through a space between an upper surface and a lower surface of the glass layer, a metal layer having at least a portion embedded in the glass layer and at least another portion exposed from the glass layer through a wall surface of the through-portion, an electronic component having at least a portion disposed in the through-portion, and an encapsulant burying at least a portion of the electronic component, the encapsulant filling at least a portion of the through-portion.

According to another aspect of the present disclosure, there is provided an electronic component-embedded substrate including a glass layer, a through-portion passing through a space between an upper surface and a lower surface of the glass layer, a plurality of metal layers respectively disposed on the inside of the glass layer, the plurality of metal layers respectively providing at least a portion of a wall surface of the through-portion, the plurality of metal layers spaced apart from each other, an electronic component having at least a portion disposed in the through-portion, and an insulating body covering at least a portion of each of the glass layer, the plurality of metal layers, and the electronic component, the insulating body filling at least a portion of the through-portion.

According to example embodiments of the present disclosure, an electronic component-embedded substrate including a glass layer in which a through-portion is formed for embedding an electronic component may prevent breakage or cracks from occurring in glass during a process of processing the through-portion and/or a process of disposing the electronic component in the through-portion, thereby improving yield.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example electronic device system;

FIG. 2 is a schematic cross-sectional view of an example electronic component-embedded board;

FIG. 3 is a schematic cross-sectional plan view of the electronic component-embedded board of FIG. 2, taken along line A-A′;

FIGS. 4 and 5 are schematic process cross-sectional views of an example method for manufacturing the electronic component-embedded board of FIG. 2;

FIG. 6 is a schematic perspective view of an example operation of forming a slit in a glass layer;

FIG. 7 is a schematic perspective view of an example operation of forming a metal layer in a slit;

FIG. 8 is a schematic perspective view of an example operation of forming an insulating layer on a glass layer;

FIG. 9 is a schematic perspective view of an example operation of forming a wiring layer and a connection via in an insulating layer;

FIG. 10 is a schematic perspective view of an example operation of forming a through-portion in a glass layer;

FIG. 11 is a schematic perspective view of an example operation of disposing an electronic component in a through-portion; and

FIG. 12 is a schematic perspective view of an example operation of forming an encapsulant.

### DETAILED DESCRIPTION

Hereinafter, example embodiments of the present disclosure are described with reference to the accompanying drawings. The shapes and sizes of components in the drawings may be exaggerated or reduced for clearer description.

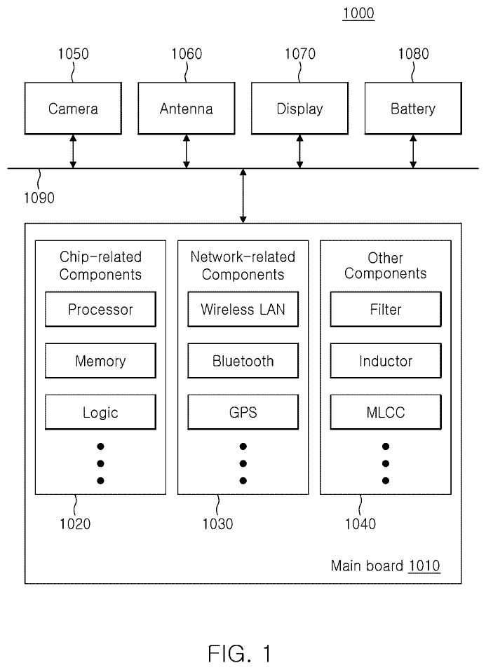

FIG. 1 is a schematic block diagram of an example of an electronic device system.

Referring to the drawings, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are not limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

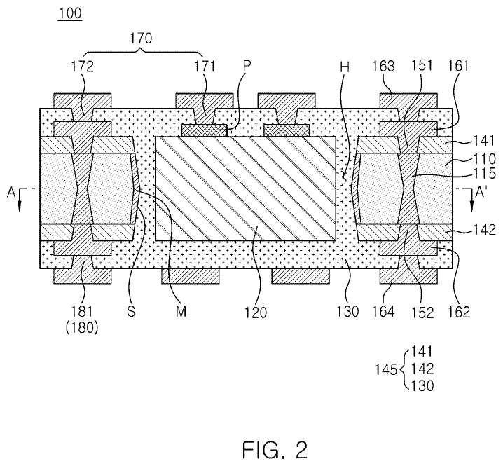

FIG. 2 is a schematic cross-sectional view of an example of an electronic component-embedded board.

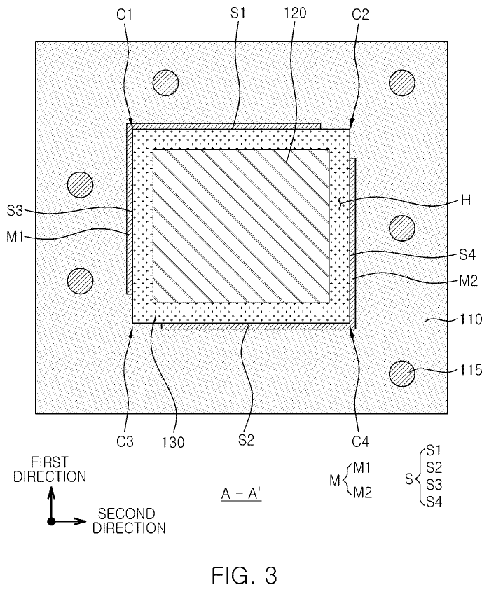

FIG. 3 is a schematic cross-sectional plan view of the electronic component-embedded board of FIG. 2, taken along line A-A′.

Referring to the drawings, an electronic component-embedded substrate 100 according to an example may include a glass layer 110, a through-portion H passing through a space between an upper surface and a lower surface of the glass layer 110, a metal layer M disposed on the inside of the glass layer 110, an electronic component 120 having at least a portion disposed in the through-portion H, and an encapsulant 130 burying at least a portion of the electronic component 120, the encapsulant 130 filling at least a portion of the through-portion H. At least a portion of the metal layer M may be embedded in the glass layer 110. At least another portion of the metal layer M may be exposed from the glass layer 110 through a wall surface S of the through-portion H. At least the exposed portion of the metal layer M may provide at least a portion of the wall surface S of the through-portion H. In plan view, the metal layer M may be embedded in the glass layer 110 and the number of surfaces of the metal layer M in contact with the glass layer 110 is greater than the number of surfaces of the metal layer M exposed from the glass layer 110 through the wall surface S of the through-portion H to be in contact with the encapsulant 130. In cross-sectional view, the metal layer M may be substantially conformally disposed to have a shape substantially corresponding to a shape of the wall surface S of the through-portion H. For example, the through-portion H may have a substantially hourglass shape in plan view. The metal layer M may have a shape bent toward the through-portion H to correspond to the shape of the through-portion H, but the present disclosure is not limited thereto.

For example, as will be described below, a slit, passing through the glass layer 110, may be processed on a cutting line of a dummy region of the glass layer 110 in which the through-portion H is to be formed, and the metal layer M may be pre-formed before the through-portion H is processed by performing plating on a wall surface of the processed slit. In this case, breakage or cracks in the glass layer 110 in a cutting process for forming the through-portion H may be prevented through the pre-formed metal layer M. In addition, the metal layer M may be disposed on the inside of the glass layer 110 even after the cutting process, as described above, thereby preventing breakage or cracks from occurring in the glass layer 110 in the process of disposing the electronic component 120 in the through-portion H through the remaining metal layer M. Accordingly, yield may be improved.

The metal layer M may include a plurality of metal layers M1 and M2. Each of the plurality of metal layers M1 and M2 may be disposed on the inside of the glass layer 110 to provide at least a portion of the wall surface S of the through-portion H. The plurality of metal layers M1 and M2 may be spaced apart from each other. For example, in plan view, at least two of the plurality of metal layers M1 and M2 may be spaced apart from each other in at least one corner region, among a plurality of corner regions C1, C2, C3, and C4 of the through-portion H. For example, the plurality of metal layers M1 and M2 may include first and second metal layers M1 and M2. In addition, in plan view, the through-portion H may have first and second wall surfaces S1 and S2 opposing each other in a first direction, and third and fourth wall surfaces S3 and S4 opposing each other in a second direction, perpendicular to the first direction. In addition, in plan view, the through-portion H may have a first corner region C1 connecting the first and third wall surfaces S1 and S3 to each other, a second corner region C2 connecting the first and fourth wall surfaces S1 and S4 to each other, and a third corner region C4 connecting the second and fourth wall surfaces S2 and S4 to each other. In this case, the first metal layer M1 may be disposed to surround the first corner region C1, the second metal layer M2 may be disposed to surround the fourth corner region C4, and the first and second metal layers M1 and M2 may be spaced apart from each other in the second and third corner regions C2 and C3.

For example, as will be described below, when the slit, passing through the glass layer 110, is processed on the cutting line of the dummy region of the glass layer 110 in which the through-portion H is to be formed, a plurality of slits spaced apart from each other may be formed as the slit. In this case, a space between the plurality of slits, for example, at least one corner region of the dummy region, may function as a bridge region, and thus the dummy region of the glass layer 110 may remain before the cutting process. As a result, the plurality of metal layers M1 and M2 spaced apart from each other, for example, the first and second metal layers M1 and M2, may be formed through the plurality of slits. Accordingly, as described above, breakage or cracks in the glass layer 110 may be effectively prevented.

Referring to the drawings, the electronic component-embedded substrate 100 according to an example may further include first and second insulating layers 141 and 142 respectively disposed on the upper surface and the lower surface of the glass layer 110. In this case, the through-portion H may collectively pass through the glass layer 110 and the first and second insulating layers 141 and 142 from an upper surface of the first insulating layer 141 to a lower surface of the second insulating layer 142. Accordingly, at least a portion of the wall surface S of the through-portion H in a region passing through the glass layer 110 may include at least a portion of each of a side surface of the metal layer M and a side surface of the glass layer 110, and at least another portion of the wall surface S of the through-portion H in a region passing through the first insulating layer 141 may include at least a portion of a side surface of the first insulating layer 141, and at least another portion of the wall surface S of the through-portion H in a region passing through the second insulating layer 142 may include at least a portion of a side surface of the second insulating layer 142.

For example, as will be described below, after the first and second insulating layers 141 and 142 are formed on the glass layer 110, the cutting process for forming the through-portion H may be performed, and thus the structure may have the above-described structural features. In addition, the encapsulant 130 may cover at least a portion of the upper surface of the first insulating layer 141 and at least a portion of the lower surface of the second insulating layer 142. In addition, each of the first and second insulating layers 141 and 142 may cover at least a portion of an upper surface and a lower surface of the metal layer M, but may not cover the side surface of the metal layer M, thereby more effectively implementing the above-described technical effects.

The first and second insulating layers 141 and 142 and the encapsulant 130 may provide an insulating body 145. The insulating body 145 may cover at least a portion of each of the glass layer 110, the metal layer M, and the electronic component 120, and may fill at least a portion of the through-portion H. The first and second insulating layers 141 and 142 and the encapsulant 130 may be integrated with each other, as necessary. For example, boundaries between the first and second insulating layers 141 and 142 and the encapsulant 130 may not be distinguished from each other. In this case, the insulating body 145 may be substantially formed of a single insulating material, and reliability may be further improved by securing adhesion. However, the present disclosure is not limited thereto.

Referring to the drawings, the electronic component-embedded substrate 100 according to an example may further include a metal via 115 passing through the glass layer, a first connection via 151 passing through the first insulating layer 141, the first connection via 151 directly connected to the metal via 115, a second connection via 152 passing through the second insulating layer 142, the second connection via 152 directly connected to the metal via 115, a first wiring layer 161 disposed on the upper surface of the first insulating layer 141, the first wiring layer 161 connected to the first connection via 151, and a second wiring layer 162 disposed on the lower surface of the second insulating layer 142, the second wiring layer 102 connected to the second connection via 152. The encapsulant 130 may cover at least a portion of each of the first and second wiring layers 161 and 162. For example, the first and second connection vias 151 and 152 may pass through a portion of the insulating body 145 on an upper side and a lower side of the glass layer 110, and the first and second wiring layers 161 and 162 may be embedded in the insulating body 145 on the upper side and the lower side of the glass layer 110, respectively. As described, a wiring may be designed on each of the first and second insulating layers 141 and 142, and an electrical connection path may be formed in the glass layer 110 and the first and second insulating layers 141 and 142. In this case, a wiring may not be directly designed on the glass layer 110, and thus reliability may be improved. Furthermore, the electrical connection path may still be shortened, and an overall thickness of the substrate may be reduced.

An upper surface and a lower surface of the metal via 115 may be substantially coplanar with the upper surface and the lower surface of the glass layer 110, respectively, or may be further recessed than the upper surface and the lower surface of the glass layer 110, respectively. From a similar point of view, the upper surface and the lower surface of the metal layer M may be substantially coplanar with the upper surface and the lower surface of the glass layer 110, respectively, or may be further recessed than the upper surface and the lower surface of the glass layer 110. For example, the metal via 115 and the metal layer M may be formed in a through-hole and a slit formed in the glass layer 110, and upper and lower sides of each of the metal via 115 and the metal layer M may be partially removed in a process of etching an over-plated portion, as necessary.

Referring to the drawings, the electronic component-embedded substrate 100 according to an example may further include a third wiring layer 163 disposed on an upper surface of the encapsulant 130, a fourth wiring layer 164 disposed on a lower surface of the encapsulant 130, a first via layer 170 passing through at least a portion of an upper side of the encapsulant 130, and a second via layer 180 passing through at least a portion of a lower side of the encapsulant 130. For example, the third and fourth wiring layers 163 and 164 may be disposed on an upper surface and a lower surface of the insulating body 145, respectively, and the first and second via layers 170 and 180 may pass through at least a portion of an upper side and a lower side of the insulating body 145, respectively. An electrode P may be disposed on an upper side of the electronic component 120. The first via layer 170 may include third and fourth connection vias 171 and 172 respectively connecting the third wiring layer 163 to the electrode P of the electronic component 150 and the first wiring layer. The second via layer 180 may include a fifth connection via 181 connecting the fourth wiring layer 164 to the second wiring layer 162. As described, a wiring may be designed on the encapsulant 130, and an electrical connection path may be formed in the encapsulant 130. Accordingly, a wiring may be designed in more various manners. In addition, the electronic component 150 may be more easily electrically connected to a wiring of a substrate through the electrode P.

The electronic component 120 may include an integrated passive device (IPD). Accordingly, parasitic inductance and parasitic capacitance may be reduced. In addition, high-frequency characteristics may be optimized, and noise may be reduced. In addition, miniaturization and a degree of integration may be improved. In addition, power efficiency may be increased. In addition, high-speed data transmission may be optimized. However, a type of the electronic component 120 is not limited thereto, and other active devices and/or passive devices may be included.

In the electronic component-embedded substrate 100 according to an example, a build-up layer may be further disposed on the upper surface and/or the lower surface of the encapsulant 130, as necessary. The build-up layer may include one or more build-up insulating layers, one or more build-up wiring layers, and one or more build-up via layers. A passivation layer may be disposed on the build-up layer. For example, the electronic component-embedded substrate 100 according to an example may have a multilayer substrate structure, and thus may be easily applied to a large-area package substrate.

Hereinafter, components of the electronic component-embedded substrate 100 according to an example will be described in more detail with reference to the drawings.

The glass layer 110 may include glass that is an amorphous solid. Glass may include, for example, pure silicon dioxide (about 100% SiO₂), soda lime glass, borosilicate glass, alumino-silicate glass, or the like, but the present disclosure is not limited thereto. An alternative glass material, such as fluorine glass, phosphate glass, chalcogen glass, or the like, may also be used as a material of the glass layer. In addition, other additives may be further included to form glass having specific physical properties. The above-described additives may include calcium carbonate (for example, lime) and sodium carbonate (for example, soda), as well as magnesium, calcium, manganese, aluminum, lead, boron, iron, chromium, potassium, sulfur, and antimony, and carbonates and/or oxides of the above-described elements and other elements. The glass layer 110 may be distinguished from an organic insulating material including a glass fiber (glass cloth and/or glass fabric), for example, a copper clad laminate (CCL), a prepreg (PPG), or the like. The glass layer 110 may be, for example, in the form of a glass plate. The through-portion H may pass through at least a space between the upper surface and the lower surface of the glass layer 110. The through-portion H may continuously surround a side surface of the electronic component 120.

The metal via 115 may be disposed in a through-hole passing through a space between the upper surface and the lower surface of the glass layer 110. The metal via 115 may be a filled via in which a through-hole is filled with a metal. For example, the metal via 115 may include a metal. The metal may include copper (Cu), aluminum (Al), silver (Ag), tin (Sn), gold (Au), nickel (Ni), lead (Pb), titanium (Ti), and/or alloys thereof. For example, the metal via 115 may include a titanium layer and a copper layer formed using sputtering, that is, sputtering titanium and sputtering copper, as a seed layer, and may include an electrolytic copper, formed using electrolytic plating based on the same, as a plating layer. As necessary, the metal via 115 may further include a chemical copper, formed using electroless plating, as the seed layer. The metal via 115 may perform various functions according to a design thereof. For example, the metal via 115 may include a through-via for signal transmission, a through-via for power transmission, a through-via for ground transmission, or the like. The metal via 115 may have a substantially cylindrical shape, but may also have a substantially hourglass shape. As necessary, the upper surface and the lower surface of the metal via 115 may be recessed further inwardly than the upper surface and the lower surface of the glass layer 110, respectively, and thus may have step portions with respect to the upper surface and the lower surface of the glass layer 110, respectively, but the present disclosure is not limited thereto. The metal via 115 may be provided as a plurality of metal vias 115.

The metal layer M may include a metal. The metal may include copper (Cu), aluminum (Al), silver (Ag), tin (Sn), gold (Au), nickel (Ni), lead (Pb), titanium (Ti), and/or alloys thereof. For example, the metal layer M may include a titanium layer and a copper layer formed using sputtering, that is, sputtering titanium and sputtering copper, as a seed layer, and may include an electrolytic copper, formed using electrolytic plating based on the same, as a plating layer. As necessary, the metal layer M may further include a chemical copper, formed using electroless plating, as the seed layer. As necessary, the upper surface and the lower surface of the metal via 115 may be recessed further inwardly than the upper surface and the lower surface of the glass layer 110, respectively, and thus may have step portions with respect to the upper surface and the lower surface of the glass layer 110, respectively, but the present disclosure is not limited thereto. The metal layer M may be provided as a plurality of metal layers M, and may include, for example, first and second metal layers M1 and M2 spaced apart from each other.

The electronic component 120 may include various types of active devices and/or passive devices. For example, the electronic component 120 may include various types of integrated circuit dies or semiconductor chips. For example, the electronic component 120 may include an integrated passive device (IPD), but the present disclosure is not limited thereto. The electronic component 120 may include an electrode P for electrical connection, and the electrode P may be disposed on an upper surface, for example, a front surface, of the electronic component 120. The electrode P may include a conductive material, for example, a metal. The metal may include copper (Cu), aluminum (Al), silver (Ag), tin (Sn), gold (Au), nickel (Ni), lead (Pb), titanium (Ti), and/or alloys thereof. The electrode P may include a pad, a bump, or a post. Alternatively, the electrode P may include a pad and a bump or post disposed on the pad. The electrode P may be provided as a plurality of electrodes P.

Each of the encapsulant 130 and the first and second insulating layers 141 and 142 may include an organic insulating material. The organic insulating material may include a thermosetting resin such as an epoxy resin, a thermoplastic resin such as polyimide, or an inorganic filler, an organic filler, and/or a glass fiber (glass cloth and/or glass fabric), together with the resin. For example, the organic insulating material may be a PPG, an Ajinomoto build-up film (ABF), a photoimageable dielectric (PID), or the like, but the present disclosure is not limited thereto. The encapsulant 130 may be formed of a plurality of layers, as necessary, and boundaries between the plurality of layers may be or may not be distinguished from each other. The encapsulant 130 and the first and second insulating layers 141 and 142 may include substantially the same insulating material. For example, the encapsulant 130 and the first and second insulating layers 141 and 142 may be integrated with each other such that boundaries therebetween are unclear. However, the present disclosure is not limited thereto, and the encapsulant 130 and the first and second insulating layers 141 and 142 may include different insulating materials, as necessary, and boundaries therebetween may also be distinguished from each other. The encapsulant 130 and the first and second insulating layers 141 and 142 may be included in the insulating body 145. The through-portion H may further pass through a space between an upper surface and a lower surface of each of the first and second insulating layers 141 and 142. The through-portion H may continuously surround the side surface of the electronic component 120.

Each of the first and second connection vias 151 and 152 may include a metal. The metal may include copper (Cu), aluminum (Al), silver (Ag), tin (Sn), gold (Au), nickel (Ni), lead (Pb), titanium (Ti), and/or alloys thereof. For example, each of the first and second connection vias 151 and 152 may include a chemical copper, formed using electroless plating, as a seed layer, and may include an electrolytic copper, formed using electrolytic plating based on the same, as a plating layer. Each of the first and second connection vias 151 and 152 may perform various functions according to a design thereof. For example, each of the first and second connection vias 151 and 152 may include a connection via for signal transmission, a connection via for power transmission, a connection via for ground transmission, or the like. Each of the first and second connection vias 151 and 152 may include a filled via in which at least a portion of a via hole is filled with a metal, but may include a conformal via in which a metal is disposed along a wall surface of a via-hole. The first and second connection vias 151 and 152 may have shapes that are substantially tapered in opposite directions. The first and second connection vias 151 and 152 may be directly connected to the upper surface and the lower surface of the metal via 115, respectively. For example, the first and second connection vias 151 and 152 may be in direct contact with the upper surface and the lower surface of the metal via 115. When the metal via 115 is provided as a plurality of metal vias 115, the first and second connection vias 151 and 152 may be provided as a plurality of first and second connection vias 151 and 152 to correspond to the plurality of metal vias 115.

Each of the first to fourth wiring layers 161, 162, 163, and 164 may include a metal. The metal may include copper (Cu), aluminum (Al), silver (Ag), tin (Sn), gold (Au), nickel (Ni), lead (Pb), titanium (Ti), and/or alloys thereof. For example, each of the first to fourth wiring layers 161, 162, 163, and 164 may include a chemical copper, formed using electroless plating, as a seed layer, and may include an electrolytic copper, formed using electrolytic plating based on the same, as a plating layer. Each of the first to fourth wiring layers 161, 162, 163, and 164 may perform various functions according to a design thereof. For example, each of the first to fourth wiring layers 161, 162, 163, and 164 may include a signal pattern, a power pattern, a ground pattern, or the like. Each of the patterns may have various forms such as a line, a trace, a plane, a land, a pad, and a land.

Each of the first and second via layers 170 and 180 may include a metal. The metal may include copper (Cu), aluminum (Al), silver (Ag), tin (Sn), gold (Au), nickel (Ni), lead (Pb), titanium (Ti), and/or alloys thereof. For example, each of the first and second via layers 170 and 180 may include a chemical copper, formed using electroless plating, as a seed layer, and may include an electrolytic copper, formed using electrolytic plating based on the same, as a plating layer. Each of the first and second via layers 170 and 180 may perform various functions according to a design thereof. For example, each of the first and second via layers 170 and 180 may include a connection via for signal transmission, a connection via for power transmission, a connection via for ground transmission, or the like. Each of the first and second via layers 170 and 180 may include a filled via in which at least a portion of a via hole is filled with a metal, but may include a conformal via in which a metal is disposed along a wall surface of a via-hole. Each of the first and second via layers 170 and 180 may include a plurality of connection vias. For example, the first via layer 170 may include third and fourth connection vias 171 and 172 respectively connecting the third wiring layer 163 to the electrode P of the electronic component 150 and the first wiring layer, and the second via layer 180 may include a fifth connection via 181 connecting the fourth wiring layer 164 to the second wiring layer 162. The connection vias included in each of the first and second via layers 170 and 180 may have shapes that are substantially tapered in opposite directions. For example, each of the third and fourth connection vias 171 and 172 may have a shape that is substantially tapered in a direction opposite to that of the fifth connection via 181.

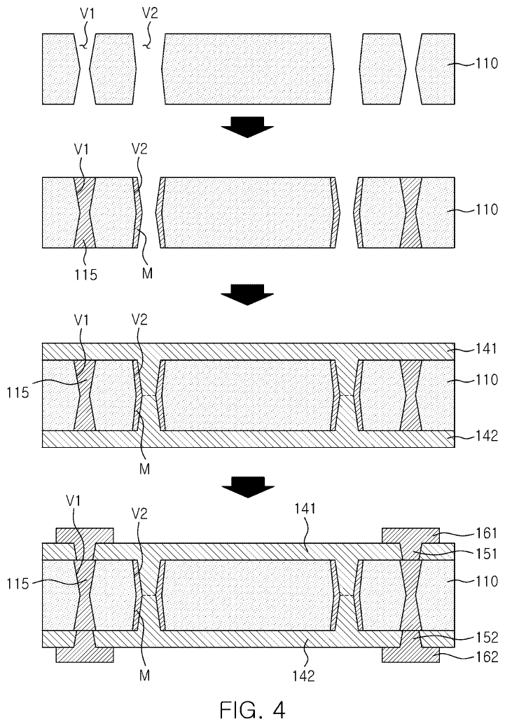

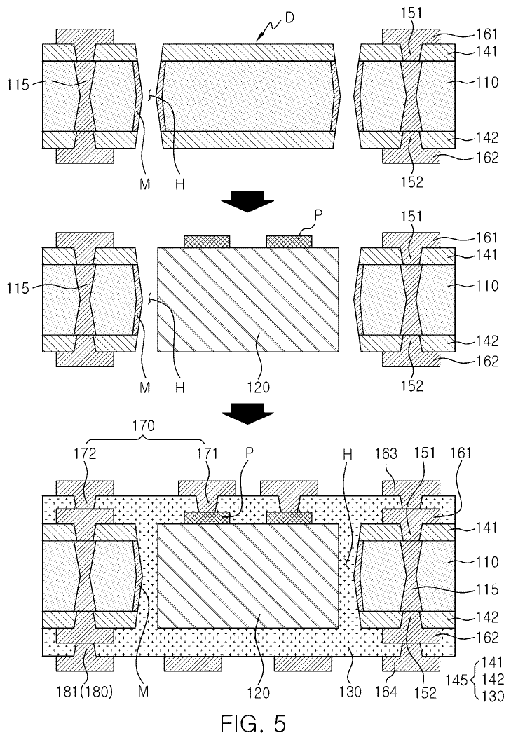

FIGS. 4 and 5 are schematic process cross-sectional views of an example method for manufacturing the electronic component-embedded board of FIG. 2.

Referring to FIG. 4, first, a through-hole V1 may be formed in a glass layer 110. The through-hole V1 may be formed using laser processing. In addition, a slit V2 may be formed in the glass layer 110. The slit V2 may be formed by performing laser processing including CO₂ laser processing and/or Yag laser processing multiple times. Subsequently, a metal via 115 and a metal layer M may be formed in the through-hole V1 and the slit V2, respectively. The metal via 115 and the metal layer M may be formed using the above-described seed layer forming process and plating process. The metal layer M may be substantially conformally formed on a wall surface of the slit V2. Subsequently, first and second insulating layers 141 and 142 may be formed on the glass layer 110. The first and second insulating layers 141 and 142 may be formed using an insulating material lamination process. At least one of the first and second insulating layers 141 and 142 may fill a space of the slit V2. Subsequently, first and second connection vias 151 and 152 and first and second wiring layers 161 and 162 may be formed in the first and second insulating layers 141 and 142. For example, after a via hole is processed in the first and second insulating layers 141 and 142 using a laser drill or the like, the first and second connection vias 151 and 152 and the first and second wiring layers 161 and 162 may be formed using the above-described seed layer formation process and plating process.

Referring to FIG. 5, subsequently, a through-portion H may be formed in the glass layer 110 and the first and second insulating layers 141 and 142. The through-portion H may be formed by performing cutting processing using a drill process. In this process, a dummy region D may be removed. In this case, cracks or breakage may be prevented from occurring in the glass layer 110 through the metal layer M. Subsequently, the electronic component 120 may be disposed in the through-portion H. In this case, cracks or breakage may be prevented from occurring in the glass layer 110 through the remaining metal layer M. Subsequently, the electronic component 120 may be embedded using the encapsulant 130. The encapsulant 130 may be formed using an insulating material lamination process or the like. In this case, an insulating body 145 including the first and second insulating layers 141 and 142 and the encapsulant 130 may be formed. In addition, a via hole may be formed in the encapsulant 130 using laser processing or the like, and plating may be performed to further form a first via layer 170 including third and fourth wiring layers 163 and 164 and third and fourth connection vias 171 and 172 described above, and a second via layer 180 including the fifth connection via 181. As necessary, a build-up process may be further performed on the encapsulant 130.

The above-described printed circuit board 100A according to an example may be manufactured through a series of processes. Other descriptions may be substantially the same as the above descriptions. In addition, descriptions of the manufacturing example may be substantially equally applicable to the above-described electronic component-embedded substrate 100 according to an example.

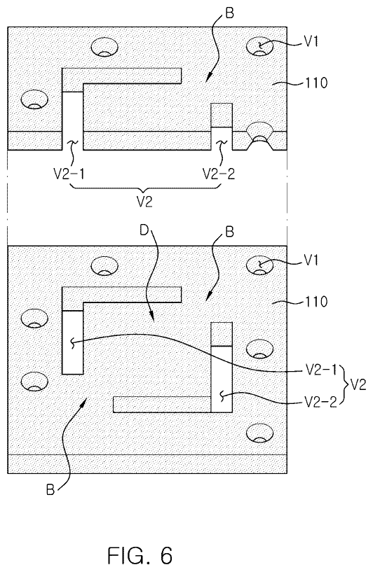

FIG. 6 is a schematic perspective view of an example operation of forming a slit in a glass layer. In the drawing, a lower portion illustrates an overall perspective view, and an upper portion illustrates a cut-away perspective view arbitrarily cut for ease of description.

Referring to the drawing, a slit V2 passing through a glass layer 110 may be processed on a cutting line of a dummy region D of the glass layer 110. In this case, the slit V2 may include a plurality of slits V2-1 and V2-2 spaced apart from each other. The plurality of slits V2-1 and V2-2 may include, for example, first and second slits V2-1 and V2-2. Spaces between the first and second slits V2-1 and V2-2 may be corner regions of the dummy region. Each of the corner regions may function as a bridge region B, and thus the dummy region D of the glass layer 110 may remain before cutting processing is performed. The first and second slits V2-1 and V2-2 may be widened by performing laser processing multiple times. Other descriptions may be substantially the same as the above descriptions, and descriptions provided herein may be substantially equally applicable to the above-described electronic component-embedded substrate 100 according to an example.

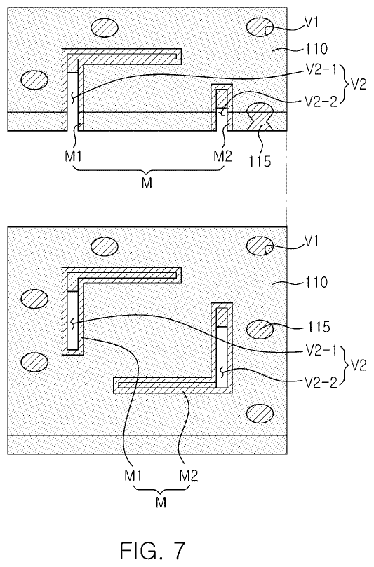

FIG. 7 is a schematic perspective view of an example operation of forming a metal layer in a slit. In the drawing, a lower portion illustrates an overall perspective view, and an upper portion illustrates a cut-away perspective view arbitrarily cut for ease of description.

Referring to the drawing, when a metal via 115 is formed in a through-hole V1 by plating, a metal layer M may be formed on a wall surface of a slit V2. For example, first and second metal layers M1 and M2 may be formed on wall surfaces of the first and second slits V2-1 and V2-2, respectively. The first metal layer M1 may be formed substantially conformally in the first slit V2-1, and thus, an empty space may be present in the first slit V2-1. The second metal layer M2 may also be formed substantially conformally in the second slit V2-2, and thus, an empty space may also be present in the second slit V2-2. The first and second metal layers M1 and M2 may be spaced apart from each other through a bridge region B described above. Other descriptions may be substantially the same as the above descriptions, and descriptions provided herein may be substantially equally applicable to the above-described electronic component-embedded substrate 100 according to an example.

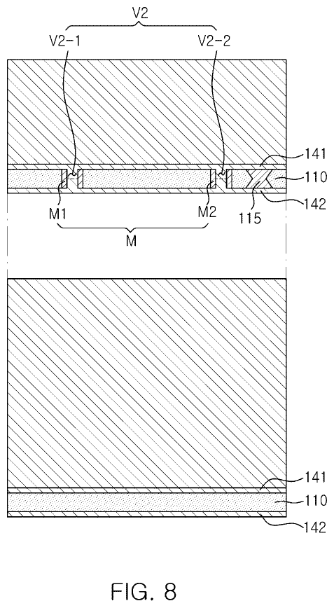

FIG. 8 is a schematic perspective view of an example operation of forming an insulating layer on a glass layer. In the drawing, a lower portion illustrates an overall perspective view, and an upper portion illustrates a cut-away perspective view arbitrarily cut for ease of description.

Referring to the drawing, first and second insulating layers 141 and 142 may be formed on a glass layer 110. For example, the first insulating layer 141 may be formed on an upper surface of the glass layer 110, and the second insulating layer 142 may be formed on a lower surface of the glass layer 110. At least one of the first and second insulating layers 141 and 142 may fill spaces of the first and second slits V2-1 and V2-2, respectively. Other descriptions may be substantially the same as the above descriptions, and descriptions provided herein may be substantially equally applicable to the above-described electronic component-embedded substrate 100 according to an example.

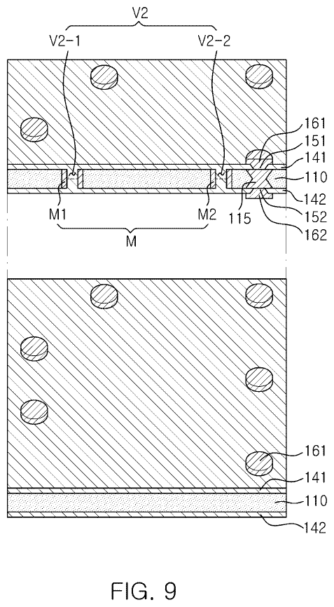

FIG. 9 is a schematic perspective view of an example operation of forming a wiring layer and a connection via in an insulating layer. In the drawing, a lower portion illustrates an overall perspective view, and an upper portion illustrates a cut-away perspective view arbitrarily cut for ease of description.

Referring to the drawing, first and second connection vias 151 and 152 and first and second wiring layers 161 and 162 may be formed on first and second insulating layers 141 and 142.

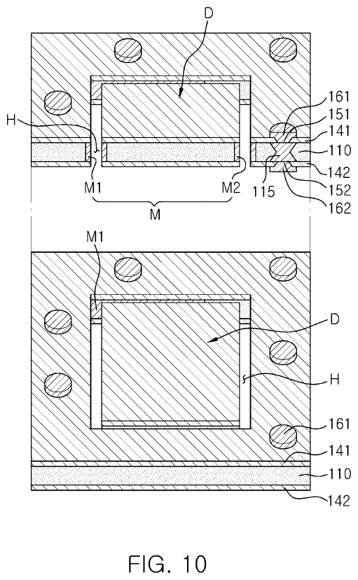

FIG. 10 is a schematic perspective view of an example operation of forming a through-portion in a glass layer. In the drawing, a lower portion illustrates an overall perspective view, and an upper portion illustrates a cut-away perspective view arbitrarily cut for ease of description.

Referring to the drawing, a cut region may be processed such that a dummy region D is removed. In this case, a bridge region B described above may also be processed and removed. Accordingly, the dummy region D may be separated and removed, and a through-portion H may be formed. In this case, cracks or breakage may be prevented from occurring in the glass layer 110 through first and second metal layers M1 and M2. Other descriptions may be substantially the same as the above descriptions, and descriptions provided herein may be substantially equally applicable to the above-described electronic component-embedded substrate 100 according to an example.

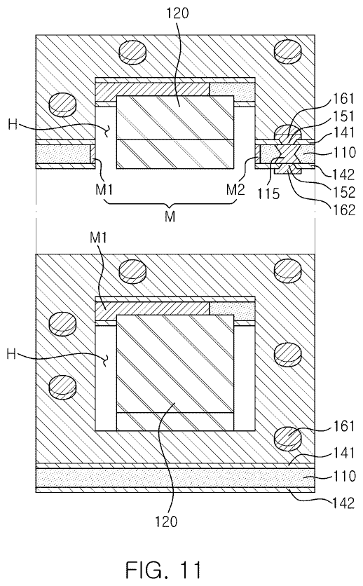

FIG. 11 is a schematic perspective view of an example of an operation of disposing an electronic component in a through-portion. In the drawing, a lower portion illustrates an overall perspective view, and an upper portion illustrates a cut-away perspective view arbitrarily cut for ease of description.

Referring to the drawing, an electronic component 120 may be disposed in a through-portion H. In this case, a glass layer 110 may be protected from impacts caused by collision through remaining first and second metal layers M1 and M2, thereby preventing cracks or breakage from occurring. Other descriptions may be substantially the same as the above descriptions, and descriptions provided herein may be substantially equally applicable to the above-described electronic component-embedded substrate 100 according to an example.

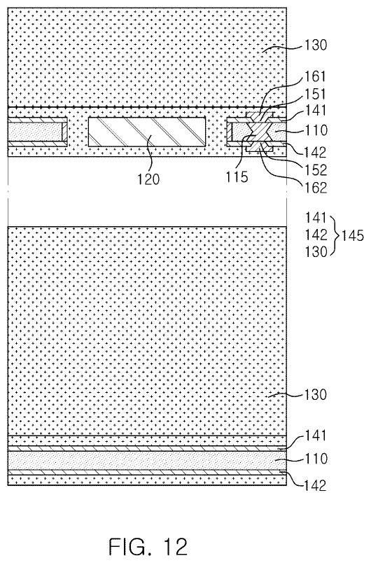

FIG. 12 is a schematic perspective view of an example of an operation of forming an encapsulant. In the drawing, a lower portion illustrates an overall perspective view, and an upper portion illustrates a cut-away perspective view arbitrarily cut for ease of description.

Referring to the drawing, an electronic component 120 may be fixed using an encapsulant 130, and the electronic component 120 may be embedded in a substrate. In this case, an insulating body 145 including first and second insulating layers 141 and 142 and the encapsulant 130 may be formed. Other descriptions may be substantially the same as the above descriptions, and descriptions provided herein may be substantially equally applicable to the above-described electronic component-embedded substrate 100 according to an example.

As used herein, the terms “cover,” “to cover,” and “covering” may include not only entirely covering but also at least partially covering, and may include not only directly covering but also indirectly covering. In addition, the terms “fill,” “to fill,” and “filling” may include not only entirely filling but also at least partially filling, and may also include approximately filling. For example, the terms may include a case in which some voids, pores or the like are present. In addition, the terms “surround,” “to surround,” and “surrounding” may include not only entirely surrounding but also partially surrounding, and may also include approximately surrounding. In addition, the terms “exposing” may include not only entirely exposing a structure but also exposing at least a portion of the structure, and the term “exposure” may mean exposing a component from another component in which the component is embedded.

As used herein, being disposed in a through-portion or a through-hole may include not only a case in which an object is completely disposed in the through-portion or the through-hole, but also a case in which a portion of an object protrudes upwardly or downwardly in cross-section. For example, in plan view, a case in which an object is disposed in the through-portion or the through-hole may be determined in a broader sense.

As used herein, a process error or a positional deviation occurring in a manufacturing process, an error in measurement, and the like may be included. For example, “having a substantially specific shape” may include not only “having a completely specific shape” but also “having an approximately specific shape.” In addition, the same insulating material may mean not only the exact same insulating material, but also the same type of insulating material. Thus, compositions of insulating materials may be substantially the same, but specific composition ratios thereof may slightly vary.

As used herein, “in cross-section” may refer to a cross-sectional shape of an object when the object is vertically cut, or a cross-sectional shape of the object when the object is viewed in a side-view. In addition, a shape in plan view may be a shape of the object when the object is horizontally cut, or a planar shape of the object when the object is viewed in a top view or a bottom-view.

As used herein, an upper side, an upper portion, the upper surface, or the like is used to refer to a downward direction based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper” and “lower” may change at any time.

As used herein, the term “connected” may not only refer to “directly connected” but also “indirectly connected” by means of an adhesive layer or the like. The term “electrically connected” may include both a case in which components are “physically connected” and a case in which components are “not physically connected.” In addition, the terms “first,” “second,” and the like may be used to distinguish a component from another component, and may not imply any particular order and/or importance, or others in relation to the components. In some cases, a first component may be referred to as a second component, and similarly, a second component may be referred to as a first component without departing from the scope of the example embodiments.

As used herein, thickness, width, length, depth, line width, spacing, pitch, separation distance, and surface roughness may be measured using a scanning microscope or an optical microscope based on a cross-section obtained by polishing or cutting an electronic component-embedded substrate. The cross-section may be a vertical cross-section or a horizontal cross-section, and each value may be measured based on a required cross-section. For example, a width of an upper end and/or a lower end of a via may be measured based on a cross-section obtained by cutting along a central axis of the via. In this case, when measured values are not consistent, the value may be determined as an average value of values measured at arbitrary five points.

As used herein, the term “an example” does not mean the same example embodiment, and is provided to emphasize different unique features. However, the examples presented above do not preclude implementation in combination with features of other examples. For example, a specific feature is described in one example but not in another, it may still be understood as being applicable to the other example, unless there is an explicit contradiction or inconsistency with what is described in that other example.

The terms used herein describe particular examples only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. An electronic component-embedded substrate comprising:
a glass layer;
a through-portion passing through a space between an upper surface and a lower surface of the glass layer;
a metal layer having at least a portion embedded in the glass layer and at least another portion exposed from the glass layer through a wall surface of the through-portion;
an electronic component having at least a portion disposed in the through-portion; and
an encapsulant burying at least a portion of the electronic component, the encapsulant filling at least a portion of the through-portion.

2. The electronic component-embedded substrate of claim 1, wherein in plan view, number of surfaces of the metal layer in contact with the glass layer is greater than number of surfaces of the metal layer in contact with the encapsulant.

3. The electronic component-embedded substrate of claim 1, wherein
the metal layer includes first and second metal layers, and
in plan view, the first and second metal layers are spaced apart from each other in at least one corner region, among a plurality of corner regions of the through-portion.

4. The electronic component-embedded substrate of claim 3, wherein
in plan view,
the through-portion has first and second wall surfaces opposing each other in a first direction and third and fourth wall surfaces opposing each other in a second direction, perpendicular to the first direction,
the through-portion has a first corner region connecting the first and third wall surfaces to each other, a second corner region connecting the first and fourth wall surfaces to each other, a third corner region connecting the second and third wall surfaces to each other, and a fourth corner region connecting the second and fourth wall surfaces to each other,
the first metal layer is disposed to surround the first corner region,
the second metal layer is disposed to surround the fourth corner region, and
the first and second metal layers are spaced apart from each other in the second and third corner regions.

5. The electronic component-embedded substrate of claim 1, wherein
the through-portion has a substantially hourglass shape in cross-sectional view, and
the metal layer is substantially conformally disposed to have a shape substantially corresponding to a shape of the wall surface of the through-portion in cross-sectional view.

6. The electronic component-embedded substrate of claim 1, further comprising:
a first insulating layer disposed on the upper surface of the glass layer; and
a second insulating layer disposed on the lower surface of the glass layer,
wherein the through-portion collectively passes through the glass layer and the first and second insulating layers from an upper surface of the first insulating layer to a lower surface of the second insulating layer, and
the encapsulant covers at least a portion of the upper surface of the first insulating layer and at least a portion of the lower surface of the second insulating layer.

7. The electronic component-embedded substrate of claim 6, wherein the first and second insulating layers and the encapsulant are integrated with each other.

8. The electronic component-embedded substrate of claim 6, wherein
the first insulating layer covers at least a portion of an upper surface of the metal layer,
the second insulating layer covers at least a portion of a lower surface of the metal layer, and
the first and second insulating layers do not cover a side surface of the metal layer, respectively.

9. The electronic component-embedded substrate of claim 6, wherein an upper surface and a lower surface of the metal layer are either (i) substantially coplanar with the upper surface and the lower surface of the glass layer, respectively, or (ii) further recessed than the upper surface and the lower surface of the glass layer, respectively.

10. The electronic component-embedded substrate of claim 6, wherein
at least a portion of the wall surface of the through-portion in a region passing through the glass layer includes at least a portion of each of a side surface of the metal layer and a side surface of the glass layer,
at least another portion of the wall surface of the through-portion in a region passing through the first insulating layer includes at least a portion of a side surface of the first insulating layer, and
at least another portion of the wall surface of the through-portion in a region passing through the second insulating layer includes at least a portion of a side surface of the second insulating layer.

11. The electronic component-embedded substrate of claim 6, further comprising:
a metal via passing through the glass layer;
a first connection via passing through the first insulating layer, the first connection via directly connected to the metal via;
a second connection via passing through the second insulating layer, the second connection via directly connected to the metal via;
a first wiring layer disposed on the upper surface of the first insulating layer; and
a second wiring layer disposed on the lower surface of the second insulating layer,
wherein the first and second connection vias are connected to the first and second wiring layers, respectively, and
the encapsulant covers at least a portion of each of the first and second wiring layers.

12. The electronic component-embedded substrate of claim 11, wherein an upper surface and a lower surface of the metal via are either (i) substantially coplanar with the upper surface and the lower surface of the glass layer, respectively, or (ii) further recessed than the upper surface and the lower surface of the glass layer, respectively.

13. The electronic component-embedded substrate of claim 11, further comprising:
a third wiring layer disposed on an upper surface of the encapsulant;
a fourth wiring layer disposed on a lower surface of the encapsulant;
a first via layer passing through at least a portion of an upper side of the encapsulant; and
a second via layer passing through at least a portion of a lower side of the encapsulant,
wherein an electrode is disposed on an upper side of the electronic component,
the first via layer includes third and fourth connection vias respectively connecting the third wiring layer to the electrode of the electronic component and the first wiring layer, and
the second via layer includes a fifth connection via connecting the fourth wiring layer to the second wiring layer.

14. The electronic component-embedded substrate of claim 13, wherein the electronic component includes an integrated passive device (IPD).

15. The electronic component-embedded substrate of claim 1,
wherein the glass layer includes a dummy region in which the through-portion is disposed, and
the metal layer is disposed on a wall surface of a slit along a cutting line of the dummy region.

16. An electronic component-embedded substrate comprising:
a glass layer;
a through-portion passing through a space between an upper surface and a lower surface of the glass layer;
a plurality of metal layers respectively disposed on an inside of the glass layer, the plurality of metal layers respectively providing at least a portion of a wall surface of the through-portion, the plurality of metal layers spaced apart from each other;
an electronic component having at least a portion disposed in the through-portion; and
an insulating body covering at least a portion of each of the glass layer, the plurality of metal layers, and the electronic component, the insulating body filling at least a portion of the through-portion.

17. The electronic component-embedded substrate of claim 16, wherein in plan view, at least two of the plurality of metal layers are spaced apart from each other in at least one corner region, among a plurality of corner regions of the through-portion.

18. The electronic component-embedded substrate of claim 16, wherein
the through-portion has a substantially hourglass shape in cross-sectional view;
each of the plurality of metal layers is substantially conformally disposed to have a shape substantially corresponding to a shape of the wall surface of the through-portion in cross-sectional view.

19. The electronic component-embedded substrate of claim 16, further comprising:
a metal via passing through the glass layer;
first and second connection vias respectively passing through a portion of the insulating body on an upper side and a lower side of the glass layer, the first and second connection vias respectively directly connected to an upper surface and a lower surface of the metal via;
first and second wiring layers respectively embedded in the insulating body on the upper and lower sides of the glass layer, the first and second wiring layers respectively connected to the first and second connection vias;
third and fourth wiring layers respectively disposed on an upper surface and a lower surface of the insulating body; and
first and second via layers passing through at least portions of the upper and lower surfaces of the insulating body, respectively;
wherein an electrode is disposed on an upper side of the electronic component,
the first via layer includes third and fourth connection vias respectively connecting the third wiring layer to the electrode of the electronic component and the first wiring layer, and
the second via layer includes a fifth connection via connecting the fourth wiring layer to the second wiring layer.

20. The electronic component-embedded substrate of claim 16, wherein the glass layer includes a dummy region in which the through-portion is disposed, and
at least one of the plurality of metal layers is metal layer is disposed on a wall surface of a slit along a cutting line of the dummy region.
